(19) United States
(12) Patent Application Publication
(10) Pub. No.: US 2014/0368367 A1
(43) Pub. Date: Dec. 18, 2014

(54) CONTINUOUS-TIME SIGMA-DELTA MODULATOR AND CONTINUOUS-TIME SIGMA-DELTA MODULATING METHOD

(71) Applicant: SAMSUNG ELECTRO-MECHANICS CO., LTD., Suwon-si (KR)

(72) Inventors: Young Kil CHOI, Suwon-si (KR); Seung Chul PYO, Suwon-si (KR); Jun Kyung NA, Suwon-si (KR); Sung Tae KIM, Suwon-si (KR); Chang Hyun KIM, Suwon-si (KR)

(21) Appl. No.: 14/307,178

(22) Filed: Jun. 17, 2014

(30) Foreign Application Priority Data
Jun. 18, 2013 (KR) 10-2013-0069651

(51) Int. Cl. H03M 3/00

(52) U.S. Cl. CPC H03M 3/376; H03M 3/50
USPC 341/143

(57) ABSTRACT

Disclosed herein are a continuous-time sigma-delta modulator and a continuous-time sigma-delta modulating method. According to an exemplary embodiment of the present invention, the continuous-time sigma-delta modulator includes: an integrator receiving and integrating a signal; a quantizer quantizing an output of the integrator to be digitally output; a timer receiving the digital output of the quantizer to charge and discharge a charging and discharging capacitor according a predetermined timing so as to generate a trapezoidal waveform; and a digital-to-analog converter (DAC) outputting a digital-to-analog converted trapezoidal waveform depending on the digital output of the quantizer by using the timer to feedback the digital-to-analog converted trapezoidal waveform to be summed with a signal input to the integrator Further, the continuous-time sigma-delta modulating method is proposed.

This application claims the foreign priority benefit under 35 U.S.C. Section 119 of Korean Application No. 10-2013-0069651 entitled “Continuous-Time Sigma-Delta Modulator And Continuous-Time Sigma-Delta Modulating Method” filed on Jun. 18, 2013, which is hereby incorporated by reference in its entirety into this application.

### BACKGROUND OF THE INVENTION

1. Technical Field

The present invention relates to a continuous-time sigma-delta modulator and a continuous-time sigma-delta modulating method, and more particularly, to a continuous-time sigma-delta modulator by using a timer and a continuous-time sigma-delta modulating method.

2. Description of the Related Art

Generally, a continuous-time sigma-delta (CTSD) modulator is configured to include an active-RC integrator, a quantizer, and a feedback digital-to-analog converter (DAC).

In this configuration, an operation of each block is as follows. First, the active-RC integrator serves to sum and integrate an analog signal input to an input terminal and a feedback signal input through a feedback path. The quantizer compares an output value of the integrator with a reference voltage value within the quantizer to output a digital value corresponding thereto. The feedback DAC operates a switch of the feedback path depending on the digital value output from the quantizer to transfer an analog feedback signal to a summing node of the integrator through the feedback path.

In this case, the analog signal generated from the feedback DAC means a fed back amount and therefore is an important factor determining a performance of the CTSD modulator, for example, a signal-to-noise ratio (SNR), and the like.

Referring to FIG. 3B illustrated as the comparative example, a current DAC (I-DAC) graph representing an output signal by a general rectangular return-to-zero (RZ) feedback DAC is illustrated. The general rectangular RZ feedback DAC has a simple configuration, but has a disadvantage in that the fed back amount is changed due to a jitter component applied at the time of turning on/off a switch. In order to supplement this disadvantage, a method of allowing the rectangular RZ feedback DAC to have an output signal like an SC-DAC graph of FIG. 3B has been used. An example of the method may include a switched-capacitor-resistor DAC (SCR DAC) method or a switched-capacitor DAC (SC DAC) method. That is, a time constant curve by a switch, a capacitor, and resistors is used. In this case, the amount fed back to the summing node of the feedback signal may be less affected by a clock jitter. However, when the SC-DAC signal of FIG. 3B is applied to the summing node of an input terminal of the integrator, an operational amplifier used in the integrator needs performances, such as a high slew-rate and a wide bandwidth, to process a peak part of a signal. In this case, the slew-rate and the bandwidth are a proportional relation to current consumed in the operational amplifier. Consequently, the increased current is a cause of increasing power consumption.

### RELATED ART DOCUMENT

### Patent Document

(Patent Document 1) KR Patent No. 10-0804645 (registered on Feb. 12, 2008)

### SUMMARY OF THE INVENTION

An object of the present invention is to provide a continuous-time sigma-delta (CTSD) modulator insensitive to a clock jitter by using a timer and a continuous-time sigma-delta (CTSD) modulating method.

According to an exemplary embodiment of the present invention, there is provided a CTSD modulator, including: an integrator receiving and integrating a signal; a quantizer quantizing an output of the integrator to be digitally output; and a digital-to-analog converter (DAC) including a timer receiving the digital output of the quantizer to charge and discharge a charging and discharging capacitor according a predetermined timing so as to generate a trapezoidal waveform, and outputting a digital-to-analog converted trapezoidal waveform depending on the digital output of the quantizer by using the timer to feedback the digital-to-analog converted trapezoidal waveform to be summed with a signal input to the integrator.

The DAC may further include: a feedback switch performing a turn on/off operation depending on the digital output of the quantizer and feeding-back the trapezoidal waveform signal generated in the charging and discharging capacitor at the time of the turn on operation; a charging switch performing a turn on/off operation according to a timing control of the timer and charging the charging and discharging capacitor; and a discharging switch connected to the charging and discharging capacitor in parallel, performing the turn on/off operation depending on the timing control of the timer, and discharging the voltage charged in the charging and discharging capacitor, and the capacitor of the DAC is connected between the feedback switch and a ground terminal, is charged and discharged according to a switching of the charging and discharging switch depending on the timing control of the timer, and generates the trapezoidal waveform signal.

The DAC may further include: a first current source connected to the charging switch to supply charging power of the charging and discharging capacitor from a power voltage terminal; a second current source connected to the discharging switch to flow current in the ground terminal; and a feedback resistor connected to the feedback switch to convert a trapezoidal waveform voltage generated in the charging and discharging capacitor into a trapezoidal waveform current signal and feeding-back the converted trapezoidal waveform voltage to be summed with the signal input to the integrator at a summing node.

The trapezoidal waveform voltage may include: a first period in which a charging voltage of the charging and discharging capacitor rises at the time of the turn off operation of the discharging switch and the turn on operation of the charging switch; a second period in which a charged state of the charging and discharging capacitor is maintained at the time of the turn off operation of the discharging switch and the turn on operation of the charging switch; and a third period in which the charging voltage of the charging and discharging capacitor is discharged and falls at the time of the turn off operation of the charging switch and the turn on operation of the discharging switch.

The timer may perform a control to charge and discharge the charging and discharging capacitor in at least a high period of the digital output of the quantizer so as to generate the trapezoidal waveform voltage.

The integrator may include: an amplifier receiving a summed signal of an input signal and the fed back signal summed at a summing node at an inversion input terminal; and an integration capacitor on a feedback path between the output of the amplifier and the inversion input terminal.

The quantizer may include a comparator which receives the output of the integrator to compare with a reference signal so as to be digitally output.

The plurality of CTSD modulators may be connected in series to form a multi-order structure.

According to another exemplary embodiment of the present invention, there is provided a CTSD modulating method, including: receiving and integrating a signal in an integrator; quantizing an output of the integrator to be digitally output; and receiving the digital output, generating a trapezoidal waveform by charging and discharging a charging and discharging capacitor depending on a predetermined timing using a timer, performing digital-to-analog conversion, and outputting an analog trapezoidal waveform depending on the digital output to feedback the analog trapezoidal waveform so as to be summed with a signal input to the integrator.

The receiving the digital output, generating the trapezoidal waveform, performing digital-to-analog conversion, and outputting and feeding-back the analog trapezoidal waveform may include: receiving the digital output and generating a trapezoidal waveform voltage in the charging and discharging capacitor by charging and discharging the charging and discharging capacitor depending on the predetermined timing by using the timer; and converting the trapezoidal waveform voltage generated in the charging and discharging capacitor into a trapezoidal waveform current signal in a feedback resistor connected to the feedback switch at the time of a turn on operation of a feedback switch performing a turn on/off operation depending on the digital output and feeding-back the converted trapezoidal waveform voltage to be summed with the signal input to the integrator in a summing node.

The generating of the trapezoidal waveform voltage may include: starting the charging of the charging and discharging capacitor by supplying power of a voltage power terminal at the time of a turn on operation of a charging switch depending on a timing control of the timer; and starting the discharging of the charging voltage of the charging and discharging capacitor at the time of a turn on operation of a discharging switch connected to the charging and discharging capacitor in parallel according to the timing control of the timer.

The trapezoidal waveform voltage may include: a first period in which a charging voltage of the charging and discharging capacitor rises at the time of the turn off operation of the discharging switch and the turn on operation of the charging switch; a second period in which a charged state of the charging and discharging capacitor is maintained at the time of the turn off operation of the discharging switch and the turn on operation of the charging switch; and a third period in which the charging voltage of the charging and discharging capacitor is discharged and falls at the time of the turn off operation of the charging switch and the turn on operation of the discharging switch.

In the performing digital-to-analog conversion, the timer may perform a control to charge and discharge the charging and discharging capacitor in at least a high period of the digital output of the quantizer so as to generate the trapezoidal waveform voltage.

### BRIEF DESCRIPTION OF THE DRAWINGS

FIG. 1 is a block diagram schematically illustrating a continuous-time sigma-delta modulator according to an exemplary embodiment of the present invention.

FIG. 2 is a circuit diagram schematically illustrating a continuous-time sigma-delta modulator according to another exemplary embodiment of the present invention.

FIG. 3A is a graph schematically illustrating a DAC output in the continuous-time sigma-delta modulator according to the exemplary embodiment of the present invention.

FIG. 3B is a graph schematically illustrating a DAC output in a continuous-time sigma-delta modulator according to a comparative example of the present invention.

FIG. 4 is a flow chart schematically illustrating a continuous-time sigma-delta modulating method according to another exemplary embodiment of the present invention.

### DESCRIPTION OF THE PREFERRED EMBODIMENTS

Exemplary embodiments of the present invention for accomplishing the above-mentioned objects will be described with reference to the accompanying drawings. In the description, the same reference numerals will be used to describe the same components of which a detailed description will be omitted in order to allow those skilled in the art to understand the present invention.

In the specification, it will be understood that unless a term such as ‘directly’ is not used in a connection, coupling, or disposition relationship between one component and another component, one component may be ‘directly connected to’, ‘directly coupled to’ or ‘directly disposed to’ another element or be connected to, coupled to, or disposed to another element, having the other element intervening therebetween.

Although a singular form is used in the present description, it may include a plural form as long as it is opposite to the concept of the present invention and is not contradictory in view of interpretation or is used as a clearly different meaning. It should be understood that “include”, “have”, “comprise”, “be configured to include”, and the like, used in the present description do not exclude presence or addition of one or more other characteristic, component, or a combination thereof.

A continuous-time sigma-delta (CTSD) modulator according to an exemplary embodiment of the present invention will be described in more detail with reference to the accompanying drawings. In the specification, the same reference numerals will be used in order to describe the same components throughout the accompanying drawings.

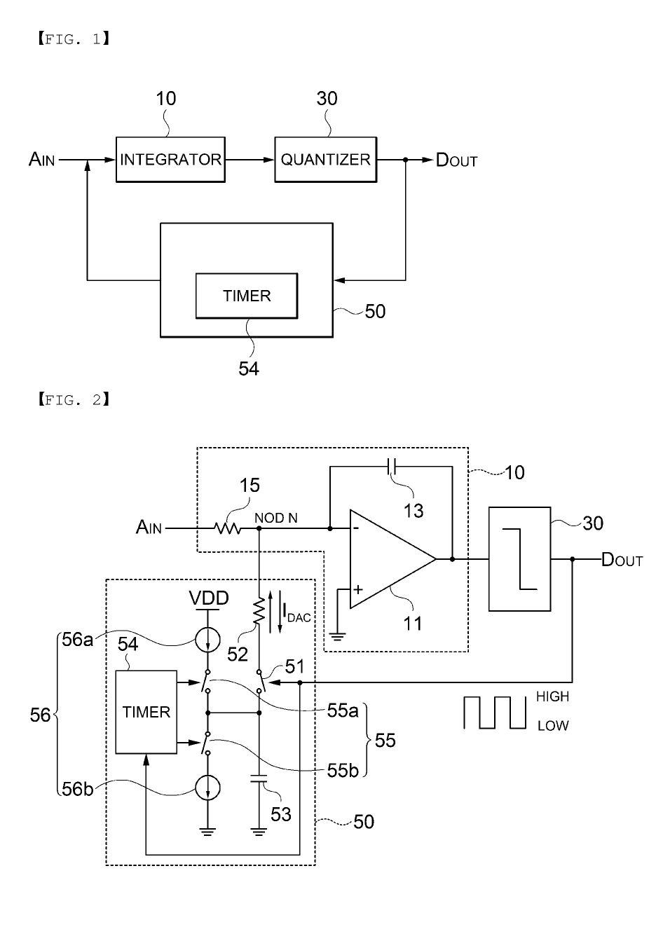

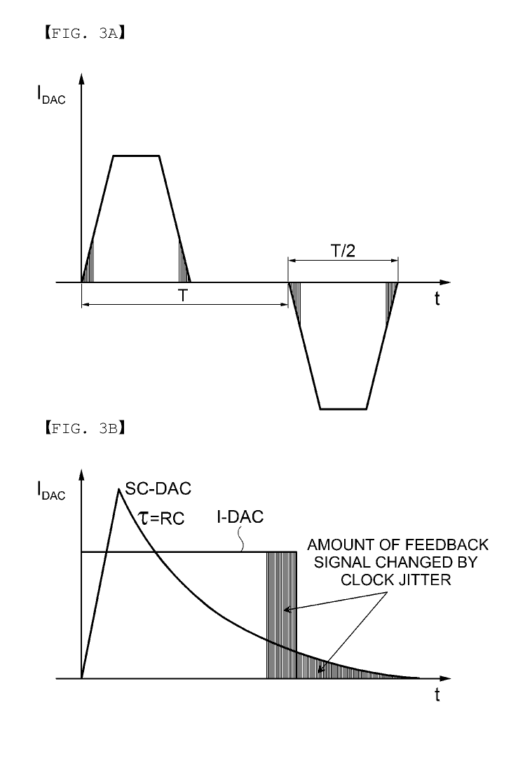

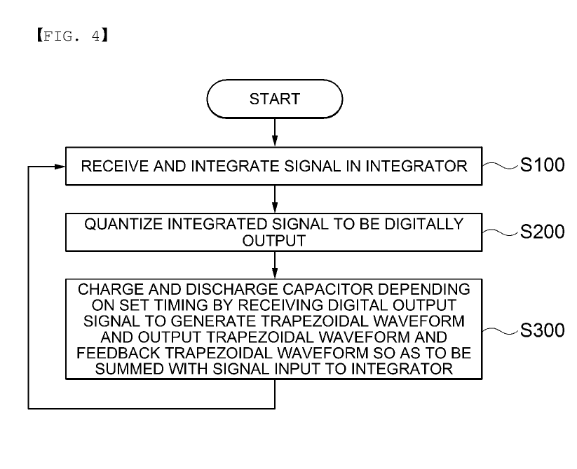

FIG. 1 is a block diagram schematically illustrating a CTSD modulator according to an exemplary embodiment of the present invention, FIG. 2 is a circuit diagram schematically illustrating a CTSD modulator according to another exemplary embodiment of the present invention, FIG. 3A is a graph schematically illustrating a DAC output in the CTSD modulator according to the exemplary embodiment of the present invention, and FIG. 3B is a graph schematically illustrating a DAC output in a CTSD modulator according to a comparative example of the present invention.

The CTSD modulator according to the exemplary embodiment of the present invention may be configured to have a primary structure and an n-order structure in which a plurality (n) of sigma-delta modulators are connected in series. Hereinafter, for simple description, each component of the CTSD modulator having the primary structure will be described in detail with reference to FIGS. 1 and/or 2, but the CTSD modulator having a multi-order structure may be implemented by connecting the plurality of CTSD modulators having a basic structure illustrated in FIGS. 1 and/or 2 in series.

Referring to FIGS. 1 and/or 2, the CTSD modulator according to one example includes an integrator 10, a quantizer 30, and a digital-to-analog converter (DAC) 50. Each component of the CTSD modulator having the primary structure will be described in detail with reference to FIGS. 1 and/or 2.

First, referring to FIGS. 1 and/or 2, the integrator 10 receives a signal input to the integrator 10 and integrates the signal. For example, referring to FIG. 2, the integrator 10 receives an input signal AIN through an input resistor 15. In this case, in detail, an input signal AIN input through an input resistor 15 and a feedback signal IDAC fed back from the DAC 50 are summed at a summing node (node N), which is then input to the integrator 10, in detail, an inversion input terminal of the amplifier 11 configuring the integrator 10 and the summed signal of the input signal AIN input through the input resistor 15 and the feedback signal IDAC is integrated. For example, the input signal AIN input to the integrator 10, in detail, the amplifier 11 through the input resistor 15 may be a single-ended signal or a differential signal.

For example, referring to FIG. 2, in one example, the integrator 10 may include the amplifier 11 and an integration capacitor 13. In this case, the amplifier 11 has the inversion input terminal receiving the summed signal of the input signal AIN and the feedback signal IDAC fed back from the DAC 50, which are summed at the summing node (node N). The integrated capacitor 13 is formed on a feedback path between an output terminal and the inversion input terminal of the amplifier 11.

Next, referring to FIGS. 1 and/or 2, the quantizer 30 quantizes the output of the integrator 10 to be digitally output. For example, the quantizer 30 receives the output of the integrator 10 to compare with the reference signal so as to output a digital signal quantized into low and high states.

For example, the quantizer 30 may be configured to include a comparator 30 which receives the output of the integrator 10 to compare with the reference signal so as to be digitally output.

To be continued, the DAC 50 will be described in detail with reference to FIGS. 1 and/or 2. Referring to FIGS. 1 and/or 2, the DAC 50 feedbacks the digital-to-analog converted signal depending on the digital output of the quantizer 30 to be summed with the signal input to the integrator 10.

For example, the DAC 50 may include a timer 54. In this case, the timer 54 receives the digital output of the quantizer 30 to charge and discharge a charging and discharging capacitor 53 depending on a predetermined timing, thereby generating a trapezoidal waveform. Therefore, the DAC 50 may use a timer 54 to output and feedback the digital-to-analog converted trapezoidal waveform depending on the digital output of the quantizer 30.

For example, according to another example, the timer 54 may perform a control to charge and discharge the charging and discharging capacitor 53 in at least a high period of the digital output of the quantizer 30 to generate a trapezoidal waveform voltage. For example, the trapezoidal waveform voltage is generated in the high period of the digital output of the quantizer 30 and the operation of the timer 54 may be turned off in the low period of the digital output of the quantizer 30 and the charging and discharging capacitor 53 may be maintained in the discharged state. Alternatively, in one example, in the timer 54, the feedback switch 51 is turned on/off depending on the digital output of the quantizer 30, separately from a timing active period and a timing inactive period depending on the digital output of the quantizer 30 and a turn on period of the feedback switch 51 is synchronized with a timing active period of the timer 54, such that the trapezoidal waveform voltage generated in the charging and discharging capacitor 53 by the timer 54 may be fed back to the integrator 10 depending on the turn on operation of the feedback switch 51.

In this case, referring to FIG. 2, in one example, the DAC 50 may further include the feedback switch 51 and the charging and discharging switch 55, in addition to the timer 54. For example, the charging and discharging switch 55 may be configured of a charging switch 55a and a discharging switch 55b. The feedback switch 51 is turned on/off depending on the digital output of the quantizer 30. The feedback switch 51 feedbacks the trapezoidal waveform signal generated in the charging and discharging capacitor 53 at the time of the turning on operation. For example, the feedback switch 51 may be configured of a MOS transistor. Further, the charging switch 55a is turned on/off according to a timing control of the timer 54 to charge the charging and discharging capacitor 53. For example, the charging switch 55a may be connected between a node between the charging and discharging capacitor 53 and the feedback switch 51 and a voltage power terminal VDD. The discharging switch 55b is connected to the charging and discharging capacitor 53 in parallel. In this case, the discharging switch 55b is turned on/off according to a timing control of the timer to discharge voltage charged in the charging and discharging capacitor 53. For example, the charging switch 55a and the discharging switch 55b may be a MOS transistor switch. In this case, the charging and discharging capacitor 53 of the DAC 50 is connected between the feedback switch 51 and a ground terminal.

Therefore, the charging and discharging capacitor 53 of the DAC 50 may be charged and discharged and generate the trapezoidal waveform voltage depending on the switching of the charging and discharging switch 55 according to the timing control of the timer 54, for example, the charging switch 55a and the discharging switch 55b. That is, a trapezoidal pulse waveform as illustrated in FIG. 3A may be generated by configuring the DAC 50 using the timer 54, for example, including the timer 54, the charging and discharging capacitor 53, and the charging and discharging switch 55. The timer 54 of the DAC 50 serves to turn on/off the charging switch 55a and the discharging switch 55b as much as the time previously set by receiving the output of the quantizer 30, for example, the comparator. In FIG. 3A, T means a period of low and high signals depending on the output of the quantizer 30, for example, the comparator. For example, in the high period of the output of the quantizer 30, for example, the comparator, the feedback switch 51 may be turned on and feedback a voltage waveform charged in the charging and discharging capacitor 53.

Referring to FIG. 2, in another example, the DAC 50 may further include a current source 56 and a feedback resistor 52. In this configuration, the current source 56 may be configured of a first current source 56a and a second current source 56b. The first current source 56a may be connected to the charging switch 55a to supply the charging power of the charging and discharging capacitor 53 from the voltage power terminal. The second current source 56b may be connected to the discharging switch 55b to flow current in the ground terminal. For example, referring to FIG. 2, the DAC 50 generating the trapezoidal waveform signal using the timer 54, the charging and discharging capacitor 53, and the first and second current sources 56a and 56b may be implemented.

Meanwhile, the feedback resistor 52 is connected to the feedback switch 51. The feedback resistor 52 serves to feedback the trapezoidal waveform signal generated in the charging and discharging capacitor 53 to the summing node (node N), together with the feedback switch 51. In this case, the feedback resistor 52 converts the trapezoidal waveform voltage generated in the charging and discharging capacitor 53 into a trapezoidal waveform current signal at the time of the turn on of the feedback switch 51 and feedbacks the trapezoidal waveform current signal to the summing node (node N). The input signal AIN input to the integrator 10, in detail, the amplifier 11 through the input resistor 15 and the feedback signal IDAC through the feedback resistor 52 are summed at the summing node (node N) and are input to the integrator 10, in detail, the amplifier 11.

Describing another example with reference to FIGS. 2 and 3A, the trapezoidal waveform voltage generated in the charging and discharging capacitor 53 includes a first period in which the charging voltage rises, a second period in which a state of charge is maintained, and a third period in which the charging voltage is discharged. That is, the first period is formed at the time of the turn off operation of the discharging switch 55b and the turn on operation of the charging switch 55a and the charging voltage of the charging and discharging capacitor 53 rises. The second period is formed at the time of the turn off operation of the discharging switch 55b and the turn off operation of the charging switch 55a and the charged state of the charging and discharging capacitor 53 is maintained. The third period is formed at the time of the turn off operation of the charging switch 55a and the turn on operation of the discharging switch 55a and the charging voltage of the charging and discharging capacitor 53 is discharged and falls.

Referring to FIGS. 2 and 3A, for example, a rising portion of the trapezoidal pulse waveform of FIG. 3 corresponds to a portion in which the charging switch 55a of FIG. 2 is turned on and a falling portion thereof corresponds to a portion in which the discharging switch 55b is turned on. In this case, a portion in which a size of the trapezoidal pulse waveform is maintained corresponds to the case in which both of the charging and discharging switches 55a and 55b are turned off. All the rising, falling, and maintained portions are kept as much as the time set in the timer 54. In FIG. 3A, the hatched period represents an amount of a feedback signal which is changed by the clock jitter.

Comparing with a comparative example illustrated in FIG. 3B, in FIG. 3B, the SC-DAC represents the feedback output signal of the DAC in the case of the sigma-delta modulator to which the switched charging and discharging capacitor 53 according to the related art is applied and in FIG. 3B, the I-DAC represents the feedback output signal of a return-to-zero (RZ) DAC in the case of the sigma-delta modulator of a general RZ DAC type. In the case of the I-DAC graph of FIG. 3B, there is a problem in that the amount fed back by the clock jitter may be greatly changed. To solve the above problem, in the case of the SC-DAC graph of FIG. 3B, the amount fed back to the summing node may be less affected by the clock jitter by using a time constant curve due to the switch, the charging and discharging capacitor 53, and the resistor, but in the case of the SC-DAC of FIG. 3B, the operational amplifier used in the integrator 10 requires performance, such as high slew-rate and a wide bandwidth, to process the peak portion of the signal, which may be a cause of increasing current consumed in the operational amplifier and increasing power consumption.

On the other hand, the trapezoidal signal waveform of FIG. 3A according to the exemplary embodiment of the present invention does not generate a peak waveform which affects the integrator 10, for example, the operational amplifier 11 configuring the integrator 10. Further, the trapezoidal signal waveform according to the exemplary embodiment of the present invention reduces the requirements of the slow-rate and the bandwidth of the integrator 10, for example, the operational amplifier 11 configuring the integrator 10. Therefore, the power consumption can be saved.

Next, the continuous-time sigma-delta (CTSD) modulating method according to an aspect of the exemplary embodiment of the present invention will be described in detail with reference to the following drawings. In this case, the CTSD modulators according to the foregoing exemplary embodiments of the present invention will be described with reference to FIGS. 1 to 3A and therefore the overlapping description thereof may be omitted.

FIG. 4 is a flow chart schematically illustrating a CTSD modulating method according to another exemplary embodiment of the present invention.

Referring to FIG. 4, the CTSD modulating method according to one example includes integrating (S100), digitally outputting (S200), and digital-to-analog converting and feeding-back (S300).

In detail, referring to FIG. 4, in the integrating (S100), the integrator 10 receives and integrates a signal. For example, referring to FIG. 2, in the integrating (S100), the integrator 10, in detail, the operational amplifier 11 configuring the integrator 10 receives the summed signal of the input signal AIN input through the input resistor 15 and the feedback signal IDAC fed back in the digital-to-analog converting and feeding-back (S300), which are summed at the summing node (node N) and integrates the received summed signal.

Next, referring to FIG. 4, in the digitally outputting (S200), the output of the integrator 10 is quantized to be digitally output. For example, in the digitally outputting (S200), the quantizer 30 of FIG. 2, for example, the comparator receives the output of the integrator 10 output in the integrating (S100) and compares the received output of the integrator 10 with the reference signal to output the digital signal quantized into a low and high state.

To be continued, referring to FIG. 4, in the digital-analog converting and feeding-back (S300), the timer 54 is used to receive the digital output so as to charge and discharge the charging and discharging capacitor 53 depending on the predetermined timing, thereby generating the trapezoidal waveform and performing the digital-to-analog conversion. In this case, the analog trapezoidal waveform is output depending on the digital output and is fedback to be summed with the signal input to the integrator 10. For example, referring to FIG. 2, in the digital-to-analog converting and feeding-back (S300), the timer 54 of the DAC 50 receives the output in the digitally outputting (S200), that is, the digital output of the quantizer 30 of FIG. 2 to charge and discharge the charging and discharging capacitor 53 depending on the predetermined timing, thereby generating the trapezoidal waveform and converting the digital output signal into the analog signal. Therefore, in the digital-to-analog converting and feeding-back (S300), the DAC 50 of FIG. 2 uses the timer 54 depending on the digital output in the digitally outputting (S200) to output and feedback the digital-to-analog converted trapezoidal waveform.

According to one example, in the digital-to-analog converting in the digital-to-analog converting and feeding-back (S300), the timer 54 may perform a control to charge and discharge the charging and discharging capacitor 53 in at least a high period of the digital output of the quantizer 30 to generate the trapezoidal waveform voltage.

In this case, although not illustrated, in one example, the digital-to-analog converting and feeding-back (S300) may include generating and feeding-back the trapezoidal waveform voltage. In the generating of the trapezoidal waveform voltage, the timer 54 is used to receive the digital output so as to charge and discharge the charging and discharging capacitor 53 depending on the predetermined timing, thereby generating the trapezoidal waveform voltage in the charging and discharging capacitor 53.

Next, in the feeding-back, at the time of the turn on operation of the feedback switch 51 which is turned on/off operation depending on the digital output, the trapezoidal waveform voltage generated in the charging and discharging capacitor 53 is converted into the trapezoidal waveform current signal in the feedback resistor 52 connected to the feedback switch 51 and is fedback to be summed with the signal input to the integrator 10 at the summing node. Referring to FIG. 2, in the feeding-back, the feedback signal IDAC is fedback through the feedback resistor 52 and in the integrating (S100), is summed with the input signal AIN input through the input resistor 15 at the summing node (node N) and the summed signal is fedback and is input and integrated to the integrator 10, in detail, the amplifier 11 in the integrating (S100). For example, in the feeding-back, referring to FIG. 2, the charging and discharging capacitor 53 of the DAC 50 is connected between the feedback switch 51 and the ground terminal and is charged and discharged depending on the timing control of the timer 54, thereby generating the trapezoidal waveform voltage.

For example, although not directly illustrated, referring to FIG. 2, in another example, the generating of the trapezoidal waveform voltage may include starting capacitor charging and starting capacitor discharging. In the starting of the capacitor charging, at the time of the turn on operation of the charging switch 55a depending on the timing control of the timer 54, the charging of the charging and discharging capacitor 53 starts by supplying the power of the voltage power terminal. In the starting of the capacitor discharging, at the time of the turn on operation of the discharging switch 55b connected to the charging and discharging capacitor 53 in parallel depending on the timing control of the timer 54, the charging voltage of the charging and discharging capacitor 53 starts to discharge.

In addition, referring to FIGS. 2 and 3A, in this case, the trapezoidal waveform voltage may include the first period in which the charging voltage rises, the second period in which the charged state is maintained, and the third period in which the charging voltage is discharged. That is, the first period is formed at the time of the turn off operation of the discharging switch 55b and the turn on operation of the charging switch 55a and the charging voltage of the charging and discharging capacitor 53 rises. The second period is formed at the time of the turn off operation of the discharging switch 55b and the turn off operation of the charging switch 55a and the charged state of the charging and discharging capacitor 53 is maintained. The third period is formed at the time of the turn off operation of the charging switch 55a and the turn on operation of the discharging switch 55b and the charging voltage of the charging and discharging capacitor 53 is discharged and falls.

According to exemplary embodiments of the present invention, the CTSD modulator feeding-back the trapezoidal waveform signal insensitive to the clock jitter by using the timer and the CTSD modulating method can be implemented.

Further, according to the exemplary embodiments of the present invention, the current consumption of the operational amplifier used in the integrator can be saved.

In addition, according to the exemplary embodiments of the present invention, the problem of the degradation in the performance of the CTSD modulator due to the clock jitter noise can be solved.

The accompanying drawings and the above-mentioned exemplary embodiments have been illustratively provided in order to assist in understanding of those skilled in the art to which the present invention pertains rather than limiting a scope of the present invention. In addition, exemplary embodiments according to a combination of the above-mentioned configurations may be obviously implemented by those skilled in the art. Therefore, various exemplary embodiments of the present invention may be implemented in modified forms without departing from an essential feature of the present invention. In addition, a scope of the present invention should be interpreted according to claims and includes various modifications, alterations, and equivalences made by those skilled in the art.

What is claimed is:

1. A continuous-time sigma-delta modulator, comprising:
an integrator receiving and integrating a signal;
a quantizer quantizing an output of the integrator to be digitally output; and
a digital-to-analog converter (DAC) including a timer receiving the digital output of the quantizer to charge and discharge a charging and discharging capacitor according a predetermined timing so as to generate a trapezoidal waveform, and outputting a digital-to-analog converted trapezoidal waveform depending on the digital output of the quantizer by using the timer to feedback the digital-to-analog converted trapezoidal waveform to be summed with a signal input to the integrator.

2. The continuous-time sigma-delta modulator according to claim 1, wherein the DAC further includes:
a feedback switch performing a turn on/off operation depending on the digital output of the quantizer and feeding-back the trapezoidal waveform signal generated in the charging and discharging capacitor at the time of the turn on operation;
a charging switch performing a turn on/off operation according to a timing control of the timer and charging the charging and discharging capacitor; and
a discharging switch connected to the charging and discharging capacitor in parallel, performing the turn on/off operation depending on the timing control of the timer, and discharging the voltage charged in the charging and discharging capacitor, and
the capacitor of the DAC is connected between the feedback switch and a ground terminal, is charged and discharged according to a switching of the charging and discharging switch depending on the timing control of the timer, and generates the trapezoidal waveform signal.

3. The continuous-time sigma-delta modulator according to claim 2, wherein the DAC further includes:
a first current source connected to the charging switch to supply charging power of the charging and discharging capacitor from a power voltage terminal;
a second current source connected to the discharging switch to flow current in the ground terminal; and
a feedback resistor connected to the feedback switch to convert a trapezoidal waveform voltage generated in the charging and discharging capacitor into a trapezoidal waveform current signal and feeding-back the converted trapezoidal waveform voltage to be summed with the signal input to the integrator at a summing node.

4. The continuous-time sigma-delta modulator according to claim 3, wherein the trapezoidal waveform voltage includes:
a first period in which a charging voltage of the charging and discharging capacitor rises at the time of the turn off operation of the discharging switch and the turn on operation of the charging switch;
a second period in which a charged state of the charging and discharging capacitor is maintained at the time of the turn off operation of the discharging switch and the turn off operation of the charging switch; and
a third period in which the charging voltage of the charging and discharging capacitor is discharged and falls at the time of the turn off operation of the charging switch and the turn on operation of the discharging switch.

5. The continuous-time sigma-delta modulator according to claim 1, wherein the timer performs a control to charge and discharge the charging and discharging capacitor in at least a high period of the digital output of the quantizer so as to generate the trapezoidal waveform voltage.

6. The continuous-time sigma-delta modulator according to claim 2, wherein the timer performs a control to charge and discharge the charging and discharging capacitor in at least a high period of the digital output of the quantizer so as to generate the trapezoidal waveform voltage.

7. The continuous-time sigma-delta modulator according to claim 4, wherein the timer performs a control to charge and discharge the charging and discharging capacitor in at least a high period of the digital output of the quantizer so as to generate the trapezoidal waveform voltage.

8. The continuous-time sigma-delta modulator according to claim 1, wherein the integrator includes:
an amplifier receiving a summed signal of an input signal and the fedback signal summed at a summing node at an inversion input terminal; and
an integration capacitor on a feedback path between the output of the amplifier and the inversion input terminal.

9. The continuous-time sigma-delta modulator according to claim 2, wherein the integrator includes:
an amplifier receiving a summed signal of an input signal and the fedback signal summed at a summing node at an inversion input terminal; and
an integration capacitor on a feedback path between the output of the amplifier and the inversion input terminal.

10. The continuous-time sigma-delta modulator according to claim 4, wherein the integrator includes:
an amplifier receiving a summed signal of an input signal and the fedback signal summed at a summing node at an inversion input terminal; and
an integration capacitor on a feedback path between the output of the amplifier and the inversion input terminal.

11. The continuous-time sigma-delta modulator according to claim 8, wherein the quantizer is configured of a comparator which receives the output of the integrator to compare with a reference signal so as to be digitally output.

12. The continuous-time sigma-delta modulator according to claim 1, wherein the plurality of continuous-time sigma-delta modulators are connected in series to form a multi-order structure.

13. The continuous-time sigma-delta modulator according to claim 2, wherein the plurality of continuous-time sigma-delta modulators are connected in series to form a multi-order structure.

14. The continuous-time sigma-delta modulator according to claim 4, wherein the plurality of continuous-time sigma-delta modulators are connected in series to form a multi-order structure.

15. A continuous-time sigma-delta modulating method, comprising:
receiving and integrating a signal in an integrator;
quantizing an output of the integrator to be digitally output; and
receiving the digital output, generating a trapezoidal waveform by charging and discharging a charging and discharging capacitor depending on a predetermined timing using a timer, performing digital-to-analog conversion, and outputting an analog trapezoidal waveform depending on the digital output to feedback the analog trapezoidal waveform so as to be summed with a signal input to the integrator.

16. The continuous-time sigma-delta modulating method according to claim 15, wherein the receiving the digital output, generating the trapezoidal waveform, performing digital-to-analog conversion, and outputting and feeding-back the analog trapezoidal waveform includes:
receiving the digital output and generating a trapezoidal waveform voltage in the charging and discharging capacitor by charging and discharging the charging and discharging capacitor depending on the predetermined timing by using the timer; and
converting the trapezoidal waveform voltage generated in the charging and discharging capacitor into a trapezoidal waveform current signal in a feedback resistor connected to the feedback switch at the time of a turn on operation of a feedback switch performing a turn on/off operation depending on the digital output and feeding-back the converted trapezoidal waveform voltage to be summed with the signal input to the integrator in a summing node.

17. The continuous-time sigma-delta modulating method according to claim 16, wherein the generating of the trapezoidal waveform voltage includes:
starting the charging of the charging and discharging capacitor by supplying power of a voltage power terminal at the time of a turn on operation of a charging switch depending on a timing control of the timer; and
starting the discharging of the charging voltage of the charging and discharging capacitor at the time of a turn on operation of a discharging switch connected to the charging and discharging capacitor in parallel according to the timing control of the timer.

18. The continuous-time sigma-delta modulating method according to claim 17, wherein the trapezoidal waveform voltage includes:
a first period in which a charging voltage of the charging and discharging capacitor rises at the time of the turn off operation of the discharging switch and the turn on operation of the charging switch;
a second period in which a charged state of the charging and discharging capacitor is maintained at the time of the turn off operation of the discharging switch and the turn off operation of the charging switch; and
a third period in which the charging voltage of the charging and discharging capacitor is discharged and falls at the time of the turn off operation of the charging switch and the turn on operation of the discharging switch.

19. The continuous-time sigma-delta modulating method according to claim 15, wherein in the performing digital-to-analog conversion, the timer performs a control to charge and discharge the charging and discharging capacitor in at least a high period of the digital output of the quantizer so as to generate the trapezoidal waveform voltage.

20. The continuous-time sigma-delta modulating method according to claim 16, wherein in the performing digital-to-analog conversion, the timer performs a control to charge and discharge the charging and discharging capacitor in at least a high period of the digital output of the quantizer so as to generate the trapezoidal waveform voltage.
